(19) United States
(12) Patent Application Publication
(10) Pub. No.: US 2002/0187583 A1
(43) Pub. Date: Dec. 12, 2002

(54) Method for manufacturing a hydrogen gas sensor

(76) Inventors: Ting-Chang Chang, Hsin-Chu City (TW); Po-Tsun Liu, Hsin-Chu City (TW)

Correspondence Address: POWELL, GOLDSTEIN, FRAZER & MURPHY LLP, P.O. BOX 97223, WASHINGTON, DC, 20090-7223, US

(21) Appl. No.: 09/874,528

(22) Filed: Jun. 6, 2001

(51) Int. Cl. H01L 21/00

(52) U.S. Cl. 438/49

(57) ABSTRACT

A method for manufacturing a hydrogen gas sensor is provided. A silicon layer with a rugged surface is formed on a dielectric layer over a first conductive electrode on a semiconductor substrate. The whole semiconductor substrate is placed in an aqueous solution containing metal ions in order that the silicon atoms of the silicon layer are substituted for the metal ions in the aqueous solution by a non-electroplating reduction-oxidation reaction. The result is a deposit of a metal layer having a rugged surface formed on the dielectric layer to serve as a second conductive electrode.

### BACKGROUND OF THE INVENTION

1. Field of the Invention

The present invention relates to a method for manufacturing a semiconductor gas sensor, and more particularly to a method for manufacturing a hydrogen gas sensor.

2. Description of the Prior Art

Recently, highly accurate, inexpensive gas sensors have become popular and several have been commercialized. These gas sensors have been used for the purpose of detecting the presence of gas in order to prevent a gas explosion. They also have been used in homes or public establishments to indicate existence of a fire. In these situations the gas sensor is relied upon to determine the presence of gas. A defective sensor can cause an accident. Thus, a highly accurate sensor is required.

Since the semiconductor gas sensor provides the advantages of being small in size, easy to operate, highly sensitive and the possibility of being fabricated in a single silicon chip. It is also advantageous to fabricate the semiconductor gas sensor in a single chip for mass production in order to reduce production cost. This is the reason the gas sensor manufactured in the semiconductor technique has become more important and popular.

In the respect of the detection of hydrogen gas, a conventional hydrogen gas sensor with amorphous barium strontium titanate (BST) (Ba_{X}Sr_{1-X}TiO₃) dielectric film is provided, which can obtain a polarization potential up to 4.5 V in response to 1000 ppm hydrogen gas contained in the air. This polarization potential is seven times that of a prior gas sensor of metal-oxide-semiconductor field effect transistor with a palladium gate. FIG. 1 is a schematic cross-sectional view of the conventional hydrogen gas sensor 1 with BST dielectric film. A platinum (Pt) electrode 11 served as a bottom electrode is formed on a silicon substrate 10. The amorphous BST dielectric film 12 is formed on the platinum electrode 11 and a palladium (Pd) electrode 13 is formed thereon to serve as a top electrode. A metal contact 14 is respectively formed over the platinum electrode 11 and palladium electrode 13. An adhesion layer of titanium (Ti) 15 is respectively formed between the metal contact 14 and the platinum electrode 11, and the palladium electrode 13, to improve adhesion there-between. This conventional hydrogen gas sensor 1 utilizes the palladium electrode 13 to adsorb hydrogen gases and dissociate them to hydrogen ions (H⁺ ions). The hydrogen ions change the polarization of the BST dielectric film 13, resulting in the shift of the threshold voltage of the hydrogen gas sensor 1 towards a lower voltage. The concentration of hydrogen gas is determined according to the variation of the threshold voltage. It is known that the larger the contact area of the palladium electrode 13 is, the more adsorbed hydrogen gases are, and then resulting in a significant shift of the threshold voltage. This in return improves the sensitivity of the hydrogen gas sensor 1. However, it is difficult to etch a palladium layer to form the palladium electrode 13. It's hard to say nothing of the difficulty for fabricating a palladium electrode with a large contact area.

Accordingly, it is an intention to provide a method for manufacturing a hydrogen gas sensor with a conductive electrode having a large contact area, that can avoid the conventional etching issues with conductive materials, especially conductive materials such as palladium/or platinum.

### SUMMARY OF THE INVENTION

It is an objective of the present invention to provide a method for manufacturing a hydrogen gas sensor. The present invention substitutes a metal layer for a silicon layer having a rugged surface formed on a dielectric layer by a non-electroplating reduction-oxidation reaction in an aqueous solution containing metal ions. Thereby, a metal layer with the rugged surface is deposited on the dielectric layer to serve as a top electrode of the present hydrogen gas sensor. And thus, the contact area between the top electrode and hydrogen gas is increased. The sensitivity of the present hydrogen gas sensor is also improved.

It is another objective of the present invention to provide a method for manufacturing a hydrogen gas sensor with a palladium/or platinum electrode having a large contact area that can avoid the conventional etching issue with palladium/or platinum.

In order to achieve the above objectives, the present invention provides a method for manufacturing a hydrogen gas sensor. A semiconductor substrate is provided. A first conductive electrode is formed on the semiconductor substrate. A dielectric layer is formed on the first conductive electrode. A silicon layer having a rugged surface is formed on the dielectric layer. Then, the whole semiconductor substrate is placed in an aqueous solution containing metal ions. The silicon atoms of the silicon layer with a rugged surface are substituted for the metal ions in the aqueous solution by a non-electroplating reduction-oxidation reaction. Thereby, a metal layer with a rugged surface is deposited on the dielectric layer to serve as a second conductive electrode. A conductive contact is respectively formed on the first conductive electrode and the second conductive electrode.

### BRIEF DESCRIPTION OF THE DRAWINGS

The present invention can be best understood through the following description and accompanying drawings, wherein:

FIG. 1 shows a schematic cross-sectional view of a conventional hydrogen gas sensor; and

FIG. 2A to FIG. 2F shows schematic cross sectional views of various steps of a preferred embodiment of the present invention.

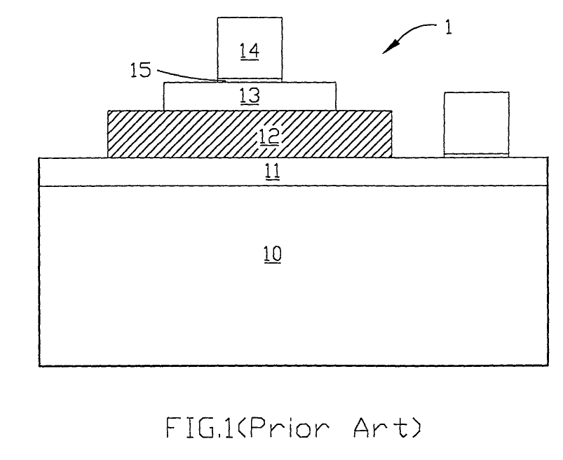

### DESCRIPTION OF THE PREFERRED EMBODIMENTS

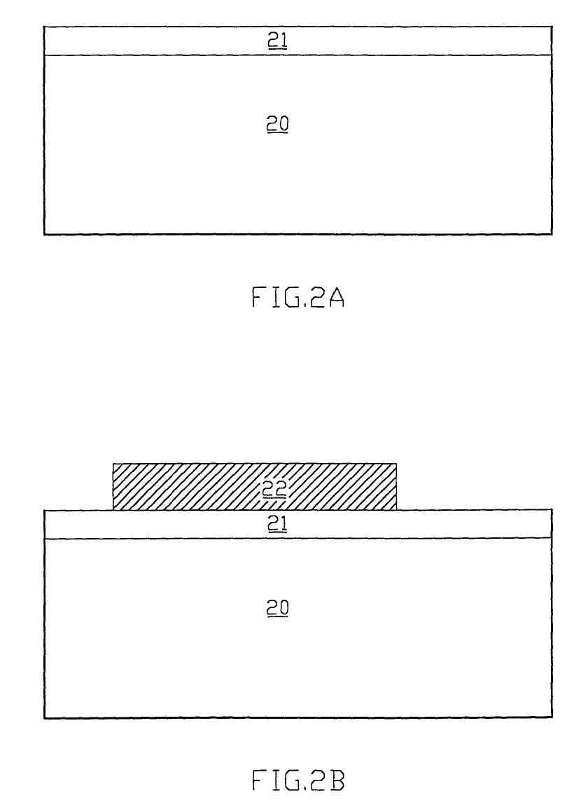

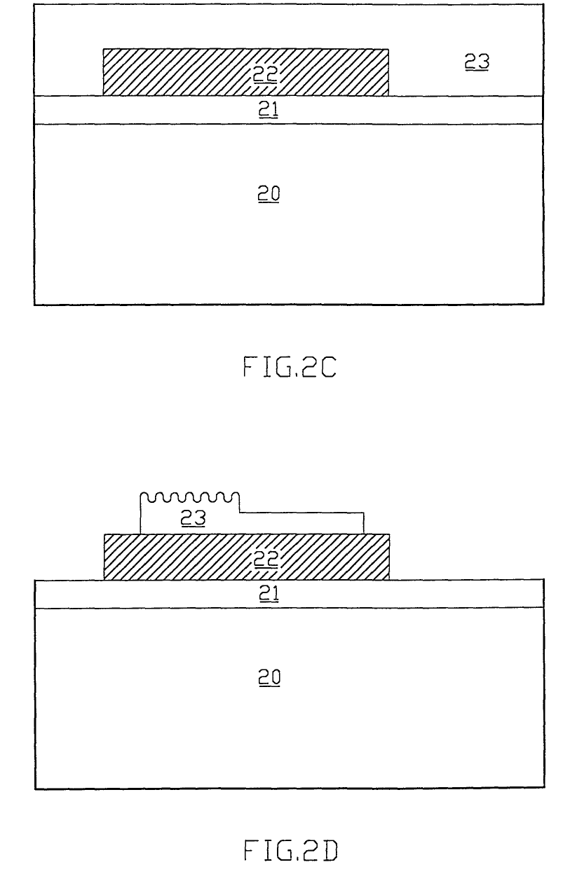

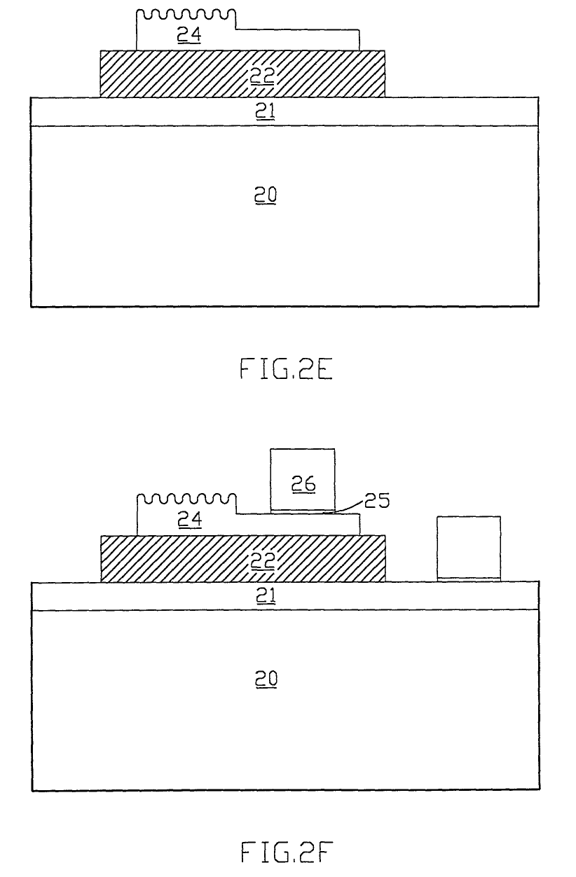

Referring to FIG. 2A, a semiconductor substrate 20 is provided. The conductivity of the semiconductor substrate 20 can be N type or P type. For example, the semiconductor substrate 20 is a P type silicon substrate. A first conductive electrode 21 is formed on the substrate 20. The first conductive electrode 21 can be made of a platinum layer deposited by a chemical vapor deposition method or a physical vapor deposition method and by way of a photolithography and etching method. The platinum layer is preferably deposited with a low temperature sputtering technique such as collimator sputtering. Referring to FIG. 2B, a dielectric layer 22, having a dielectric constant about 100˜500, such as barium strontium titanate (BST) dielectric layer, is formed on the first conductive electrode 21, and patterned to a dielectric film by the conventional photolithography and etching method.

Referring to FIG. 2C, a silicon layer 23 is formed on the dielectric layer 22. The silicon layer 23 can be an amorphous silicon layer formed by way of a chemical vapor deposition method utilizing SiH₄/or Si₂H₆ as a reaction gas. The silicon layer 23 can also be a polysilicon layer formed by way of a low-pressure chemical vapor deposition method utilizing SiH₄ as a reaction gas. Referring to FIG. 2D, a pattern with a rugged surface is transferred to the silicon layer 23 by way of the photolithography and etching method. The etching method can be a dry etching or a wet etching using an aqueous solution of hydrofluoric acid (HF) and nitric acid (HNO₃) as an etchant. The ratios of hydrofluoric acid/nitric acid/water in the aqueous solution are 1: 2˜5: 3˜10. Accordingly, the silicon layer 23 with a rugged surface, such as a crown-shaped surface, an extended fin-shaped surface etc., is provided on the dielectric layer 22.

Referring to FIG. 2E, the whole semiconductor substrate 20 is placed in an aqueous solution containing palladium ions (Pd⁺² ions), for example an aqueous solution of hydrofluoric acid (HF) containing palladium chloride (PdCl₂). The silicon atoms of the silicon layer 23 having a rugged surface are substituted for palladium ions in the aqueous solution by a non-electroplating reduction-oxidation reaction, and then a palladium layer 24 with the rugged surface is deposited on the dielectric layer 22. The palladium layer 24 with the rugged surface is used to serve for a second conductive electrode. The non-electroplating reduction-oxidation reaction (I) between the silicon layer 23 and palladium chloride in the aqueous solution of hydrofluoric acid is shown in the following:

2PdCl₂+Si+6HF→2Pd⇓+H₂SiF₆+4HCl (I)

The silicon atoms of the silicon layer 23 also can be substituted for platinum ions (Pt⁺²) in an aqueous solution by a non-electroplating reduction-oxidation reaction like reaction (I) to deposit a platinum layer with the rugged surface on the dielectric layer 22. The compound of platinum chloride (PtCl₂) can be substituted for palladium chloride in the aqueous solution of hydrofluoric acid. Then, an annealing process is preferably performed to densify the palladium layer 24. The palladium layer 24 provides a rugged surface so that the contact area between the second conductive electrode and hydrogen gas is increased.

In the present invention, the silicon atoms of the silicon layer 23 with a rugged surface are substituted for metal ions in an aqueous solution by way of a non-electroplating reduction-oxidation reaction by placing the whole semiconductor substrate 20 in the aqueous solution containing the metal ions. The metal ions, such as Pt⁺², Pd⁺², Ir⁺², Rh⁺² and Ru⁺² ions, are applicable in this non-electroplating reduction-oxidation reaction.

Referring to FIG. 2F, an adhesion layer 25 of titanium (Ti) is respectively formed on the first conductive electrode 21 and the second conductive electrode. Then, a conductive contact 26, such as a gold (Au) contact, is formed on the adhesion layer 25. The adhesion layer 25 respectively formed between the metal contact 26 and the first conductive electrode 21, and the second conductive electrode, is used to improve adhesion there-between. By the present invention, a hydrogen gas sensor with a palladium/or platinum electrode having a large contact area is provided.

The second conductive electrode formed of the palladium layer 24 provides a rugged surface so that the contact area between the second conductive electrode and hydrogen gas is increased, thus the quantity of adsorbed hydrogen gas is increased. The sensitivity of the present hydrogen gas sensor is thereby improved.

The present invention provides a method to substitute silicon atoms of a patterned silicon layer formed on a dielectric layer for metal ions in an aqueous solution by a non-electroplating reduction-oxidation reaction, to deposit a metal layer, such as a palladium layer/or a platinum layer, on the dielectric layer to serve as a top electrode, i.e. the second conductive electrode, of the present hydrogen gas sensor. Therefore, the present invention provides a method for forming a palladium/or platinum electrode, which avoids the conventional etching issue with the conductive materials like palladium/or platinum. Furthermore, the silicon layer can be patterned to have any surface shape by the photolithography and etching method. The present invention provides a hydrogen gas sensor with a palladium/or platinum electrode having a contact surface of any desired shape to efficiently increase the adsorption of hydrogen gas. Accordingly, the present invention can provide a hydrogen gas sensor with high sensitivity.

The preferred embodiments are only used to illustrate the present invention, not intended to limit the scope thereof. Many modifications of the preferred embodiments can be made without departing from the spirit of the present invention.

What is claimed is:

1. A method for manufacturing a hydrogen gas sensor, comprising:
providing a semiconductor substrate;
forming a first conductive electrode on said semiconductor substrate;
forming a dielectric layer on said first conductive electrode;
forming a silicon layer having a rugged surface on said dielectric layer;
placing said semiconductor substrate in an aqueous solution containing metal ions so that silicon atoms of said silicon layer having said rugged surface are substituted for said metal ions in said aqueous solution by a non-electroplating reduction-oxidation reaction, thereby forming a metal layer having said rugged surface on said dielectric layer to serve as a second conductive electrode; and
forming respective conductive contact on said first conductive electrode and said second conductive electrode.

2. The method of claim 1, wherein the conductivity of said semiconductor substrate is either of P type conductivity and N type conductivity.

3. The method of claim 1, wherein the dielectric constant of said dielectric layer is in the range of about 100˜500.

4. The method of claim 1, wherein said silicon layer having a rugged surface is formed by the steps of forming an amorphous silicon layer on said dielectric layer by way of a chemical vapor deposition method and patterning said amorphous silicon layer to form said silicon layer with said rugged surface by a photolithograhy and wet etching method with an aqueous solution of hydrofluoric acid and nitride acid.

5. The method of claim 4, wherein the ratios of hydrofluroic acid, nitric acid and water in the aqueous solution of hydrofluroic acid and nitric acid are 1:2˜5:3˜10.

6. The method of claim 1, wherein said silicon layer having a rugged surface is formed by the steps of forming a polysilicon layer on said dielectric layer by way of a low pressure chemical vapor deposition method utilizing SiH₄ as a reaction gas and patterning said polysilicon layer to form said silicon layer having said rugged surface by a photolithograhy and wet etching method with an aqueous solution of hydrofluoric acid and nitride acid.

7. The method of claim 6, wherein the ratios of hydrofluroic acid, nitric acid and water in the aqueous solution of hydrofluroic acid and nitric acid are 1:2˜5:3˜10.

8. The method of claim 1, wherein said silicon layer having a rugged surface is formed by the steps of forming an amorphous silicon layer on said dielectric layer by way of a chemical vapor deposition method and patterning said amorphous silicon layer to form said silicon layer with said rugged surface by a photolithograhy and dry etching method.

9. The method of claim 1, wherein said silicon layer having a rugged surface is formed by the steps of forming a polysilicon layer on said dielectric layer by way of a low pressure chemical vapor deposition method utilizing SiH₄ as a reaction gas and patterning said polysilicon layer to form said silicon layer having said rugged surface by a photolithograhy and dry etching method.

10. The method of claim 1, wherein said metal ions are selected from a group consisting of Pt⁺² ion, Pd⁺² ion, Ir⁺² ion, Rh⁺² ion and Ru⁺² ion.

11. The method of claim 1, wherein said aqueous solution containing said palladium ions (Pd⁺²) is an aqueous solution of hydrofluoric acid containing palladium chloride (PdCl₂).

12. The method of claim 1, wherein said aqueous solution containing said platinum ions (Pt⁺²) is an aqueous solution of hydrofluoric acid containing platinum chloride (PtCl₂).

13. The method of claim 1, wherein further comprising proceeding an annealing process subsequent to the formation of said metal layer having said rugged surface.
